(19) United States
(12) Patent Application Publication
(10) Pub. No.: US 2026/0180597 A1
(43) Pub. Date: Jun. 25, 2026

(54) METHOD, APPARATUS AND ELECTRONIC DEVICE FOR DATA PROCESSING

(71) Applicant: DOUYIN VISION CO., LTD., Shijingshan District, Beijing (CN)

(72) Inventor: Yongsen Jiang, Beijing (CN)

(21) Appl. No.: 19/125,906

(22) PCT Filed: Nov. 9, 2023
(86) PCT No.: PCT/CN2023/130808

§ 371 Date: Apr. 30, 2025

(30) Foreign Application Priority Data
Dec. 20, 2022 (CN) 202211649330.4

(51) Int. Cl. H03M 7/30; G06F 9/30

(52) U.S. Cl. CPC H03M 7/6005; G06F 9/30098

(57) ABSTRACT

The disclosure provides a method, apparatus and electronic device for data processing, and the method includes: obtaining 2N pieces of compressed data and 2N compression weights associated with the 2N pieces of compressed data, a bit width of the compressed data being 2 times a bit width of the compression weight, and N being a positive integer; storing, in an interleaved manner, the 2N compression weights to a first register, storing the first N pieces of compressed data in the 2N pieces of compressed data to a second register, and storing the last N pieces of compressed data in the 2N pieces of compressed data to a third register; and decompressing data in the first register, the second register, and the third register to acquire decompressed data corresponding to the 2N pieces of compressed data. The memory of the electronic device is saved, and the data decompression accuracy is improved.

This application claims priority to Chinese Patent Application No. 202211649330.4, entitled “Method, Apparatus and Electronic Device for Data Processing” filed on Dec. 20, 2022, the entire contents of which are incorporated herein by reference.

### FIELD

Embodiments of the present disclosure relate to the field of storage technologies, and in particular, to a method, apparatus and electronic device for data processing.

### BACKGROUND

The quantization compression technology can effectively reduce the storage space occupied by data. For example, since the minimum computation bit width of the electronic device is 8 bits, the data may be compressed to ¼ of the original data volume through the 8bit quantization technique.

At present, in order to further reduce the storage space occupied by data, the data may be compressed by using a quantization technique with a smaller quantization bit number than a minimum computation bit width. For example, the minimum computation bit width of the electronic device is 8bit, the data can be compressed 8 times through the 4bit quantization technique, thereby reducing the storage space occupied by the data. However, the electronic device cannot decompress the compressed data with the quantization bit number smaller than the minimum computation bit width, resulting in a lower accuracy of data decompression.

### SUMMARY

The present disclosure provides a method, apparatus and electronic device for data processing, which are used for solving the technical problem of low accuracy of data decompression in the prior art.

According to a first aspect, the present disclosure provides a method for data processing, the method comprising:
obtaining 2N pieces of compressed data and 2N compression weights associated with the 2N pieces of compressed data, a bit width of the compressed data being 2 times a bit width of the compression weight, and N being a positive integer;
storing, in an interleaved manner, the 2N compression weights to a first register, storing the first N pieces of compressed data in the 2N pieces of compressed data to a second register, and storing the last N pieces of compressed data in the 2N pieces of compressed data to a third register; and
decompressing data in the first register, the second register, and the third register to acquire decompressed data corresponding to the 2N pieces of compressed data.

According to a second aspect, the present disclosure provides an apparatus for data processing, the apparatus for data processing comprising an obtaining module, a storage module and a processing module, wherein:
the obtaining module is configured to obtain 2N pieces of compressed data and 2N compression weights associated with the 2N pieces of compressed data, a bit width of the compressed data is 2 times a bit width of the compression weight, and N is a positive integer;
the storage module is configured to store, in an interleaved manner, the 2N compression weights to a first register, store the first N pieces of compressed data in the 2N pieces of compressed data to a second register, and store the last N pieces of compressed data in the 2N pieces of compressed data to a third register; and
the processing module is configured to decompress data in the first register, the second register, and the third register to acquire decompressed data corresponding to the 2N pieces of compressed data.

According to a third aspect, an embodiment of the present disclosure provides an electronic device, comprising: a processor and a memory;
the memory storing computer-executable instructions;
the processor executing the computer-executable instructions stored in the memory, such that the processor performs the method for data processing according to the first aspect and various possible implementations of the first aspect.

According to a fourth aspect, an embodiment of the present disclosure provides a computer-readable storage medium, wherein the computer-readable storage medium stores computer-executable instructions, the computer-executable instructions, when executed by a processor, implement the method for data processing according to the first aspect and various possible implementations of the first aspect.

According to a fifth aspect, an embodiment of the present disclosure provides a computer program product, comprising a computer program, wherein the computer program, when executed by a processor, implements the method for data processing according to the first aspect and various possible implementations of the first aspect.

The present disclosure provides a method, apparatus and electronic device for data processing: obtaining 2N pieces of compressed data and 2N compression weights associated with the 2N pieces of compressed data, wherein a bit width of the compressed data is 2 times a bit width of the compression weight, and N is a positive integer; storing, in an interleaved manner, the 2N compression weights to a first register, storing the first N pieces of compressed data in the 2N pieces of compressed data to a second register, and storing the last N pieces of compressed data in the 2N pieces of compressed data to a third register; and decompressing data in the first register, the second register, and the third register to acquire decompressed data corresponding to the 2N pieces of compressed data. In the foregoing method, since the bit width of the compressed data is 2 times the bit width of the compression weight, therefor the electronic device performs low-bit quantization and compression on the compression weight to save the storage space of the electronic device, and since the electronic device stores the 2N compression weights in an interleaved manner to the first register, stores the first N pieces of compressed data in the 2N pieces of compressed data to the second register, and stores the last N pieces of compressed data in the 2N pieces of compressed data to the third register, the electronic device may respectively perform operations with the second register and the third register through the first register with a interleaved storage manner, to decompress the 2N pieces of compressed data, thereby improving accuracy of data decompression.

### BRIEF DESCRIPTION OF DRAWINGS

In order to more clearly illustrate the embodiments of the present disclosure or the technical solutions in the prior art, the accompanying drawings used in the description of the embodiments or the prior art will be briefly introduced below, and it will be apparent that the drawings in the following description are some embodiments of the present disclosure, and those skilled in the art may also obtain other drawings according to these drawings without creative labor.

FIG. 1 is a schematic diagram of an application scenario according to an embodiment of the present disclosure;

FIG. 2 is a schematic flowchart of a method for data processing according to an embodiment of the present disclosure;

FIG. 3 is a schematic diagram of a storage structure of a first register provided by an embodiment of the present disclosure;

FIG. 4 is a schematic diagram of storing compression weights in an interleaved manner according to an embodiment of the present disclosure;

FIG. 5 is a schematic diagram of a storage process of compressed data according to an embodiment of the present disclosure;

FIG. 6 is a schematic diagram of a method for obtaining decompressed data according to an embodiment of the present disclosure;

FIG. 7 is a schematic diagram of a fourth register according to an embodiment of the present disclosure;

FIG. 8A is a schematic diagram of first to-be-processed data according to an embodiment of the present disclosure;

FIG. 8B is a schematic diagram of second to-be-processed data according to an embodiment of the present disclosure;

FIG. 9 is a schematic diagram of a process of obtaining first to-be-processed data according to an embodiment of the present disclosure;

FIG. 10 is a schematic diagram of obtaining second to-be-processed data according to an embodiment of the present disclosure;

FIG. 11 is a schematic diagram of a process of obtaining decompressed data according to an embodiment of the present disclosure;

FIG. 12 is a schematic flowchart of a method for data processing according to an embodiment of the present disclosure;

FIG. 13 is a schematic structural diagram of an apparatus for data processing according to an embodiment of the present disclosure;

FIG. 14 is a schematic structural diagram of an electronic device according to an embodiment of the present disclosure.

### DETAILED DESCRIPTION

Exemplary embodiments will be described in detail herein, examples of which are illustrated in the accompanying drawings. The following description relates to the accompanying drawings, in which like numerals indicate like or similar elements unless otherwise indicated. The embodiments described in the following exemplary embodiments do not represent all embodiments consistent with the present disclosure. Rather, they are merely examples of apparatuses and methods consistent with some aspects of the disclosure as detailed in the appended claims.

For ease of understanding, the concepts involved in the embodiments of the present disclosure are described below.

An electronic device is a device having a wireless transceiver function. The electronic device may be deployed on land, including indoor or outdoor, handheld, wearable, or vehicle-mounted; or may be deployed on the water surface (for example, a ship, etc.). The electronic device may be a mobile phone, a tablet computer (Pad), a computer with a wireless transceiver function, a virtual reality (VR) electronic device, an augmented reality (AR) electronic device, a wireless terminal in industrial control, a vehicle-mounted electronic device, a wireless terminal in self-driving, a wireless electronic device in a remote medical device, a wireless electronic device in a smart grid, a wireless electronic device in transportation safety, a wireless electronic device in a smart city, a wireless electronic device in a smart home, a wearable electronic device, and the like. The electronic device according to the embodiments of the present disclosure may also be referred to as a terminal, user equipment (UE), an access electronic device, an in-vehicle terminal, an industrial control terminal, a UE unit, a UE station, a mobile terminal, a mobile station, a remote station, a remote electronic device, a mobile device, a UE electronic device, a wireless communication device, a UE agent, or a UE device. The electronic device may also be stationary or mobile.

In the related art, the quantization compression technology can effectively reduce the storage space occupied by the data. For example, the data may be compressed by using a 8bit quantization technique, and the data may be compressed into ¼ of the original data. At present, when data compression is performed, a quantization bit number is determined based on a minimum computation bit width of a CPU in an electronic device. For example, if the minimum computation bit width of the CPU is 8bit, a 8bit quantization compression technique is used when data compression is performed.

However, in order to further compress the data, the data may be compressed by using a quantization technique with a smaller quantization bit number than the minimum computation bit width. For example, when the model is compressed, the quantization compression technology of 8bit can only compress the model to ¼ of the original data, and the quantization compression technology of 4bit can compress the model to ⅛ of the original data, which facilitates the model to be set in the terminal. However, since the minimum computation bit width of the electronic device is 8bit, for the compressed data of 4bit, the electronic device still needs to process according to the decompression method of 8bit, such that the compressed data cannot be multiplied with the corresponding compression weight, thereby resulting in lower accuracy of data decompression.

In order to solve the technical problem in the related art, the embodiment of the present disclosure provides a method for data processing, comprising: obtaining 2N pieces of compressed data and 2N compression weights associated with the 2N pieces of the compressed data, wherein the bit width of the compressed data is 2 times the bit width of the compression weight, N is a positive integer; respectively storing the first N compression weights in the high bits in the N storage units of the first register, respectively storing the last N compression weights in the low bits in the N storage unit; storing the first N pieces of compressed data in the 2N pieces of compressed data into a second register, storing the last N pieces of compressed data in the 2N pieces of compressed data into a third register, and decompressing the data in the first register, the second register and the third register to acquire decompressed data corresponding to the 2N pieces of compressed data. In this way, since the 2N compression weights are stored in the first register in an interleaved manner, therefore, the first N compression weights may be respectively multiplied by the first N pieces of compressed data in the second register, and the last N compression weights may be respectively multiplied by the last N pieces of compressed data in the third register, thereby decompressing the 2N pieces of compressed data, and improving the accuracy of data decompression.

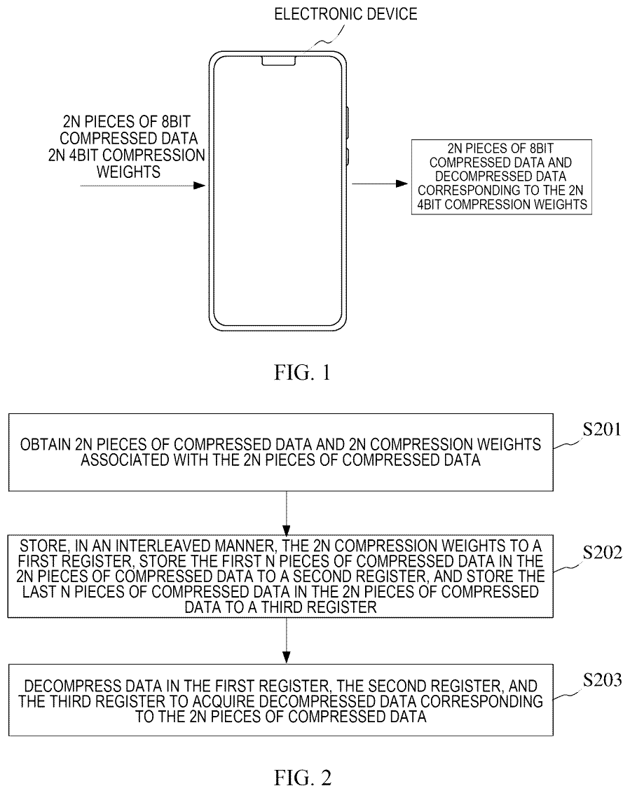

An application scenario of an embodiment of the present disclosure will be described below with reference to FIG. 1.

FIG. 1 is a schematic diagram of an application scenario according to an embodiment of the present disclosure. Referring to FIG. 1, an electronic device is provided. Wherein, the minimum computation bit width of the electronic device is 8bit. The 2N pieces of 8bit compressed data and the 2N pieces of 4bit compression weights corresponding to the 2N pieces of compressed data are input to the electronic device, the electronic device may store, in an interleaved manner, the 2N 4bit compression weights in the first register, and register the first N pieces of compressed data in the second register, and register the last N pieces of compressed data in the third register, and the electronic device may respectively multiply the compressed data in the second register and the third register based on the 2N compression weights stored interleaved in the first register, to acquire the decompressed data corresponding to the 2N pieces of 8 bit compressed data and the 2N pieces of 4bit compressed weights. In this way, since the 2N compression weights are stored in the first register in an interleaved manner, the first N compression weights may be respectively multiplied by the first N pieces of compressed data in the second register, and the last N compression weights may be respectively multiplied by the last N pieces of compressed data in the third register, thereby decompressing the 2N pieces of compressed data, and improving the accuracy of data decompression.

It should be noted that FIG. 1 merely illustrates an application scenario of the embodiments of the present disclosure in an example form, and does not limit the application scenario of the embodiments of the present disclosure.

The technical solutions of the present disclosure and how the technical solutions of the present disclosure solve the above mentioned technical problem are described in detail below with reference to specific embodiments. The following several specific embodiments may be combined with each other, and the same or similar concepts or processes may not be repeated in some embodiments. Embodiments of the present disclosure will be described below with reference to the accompanying drawings.

FIG. 2 is a schematic flowchart of a method for data processing according to an embodiment of the present disclosure. Referring to FIG. 2, the method may include the following steps.

S201: obtain 2N pieces of compressed data and 2N compression weights associated with the 2N pieces of compressed data.

The executing body of the embodiment of the present disclosure may be an electronic device or a apparatus for data processing disposed in the electronic device. Optionally, the apparatus for data processing may be implemented by software, and the apparatus for data processing may also be implemented by using software and hardware, which is not limited in the embodiments of the present disclosure.

Optionally, the compressed data may be data after data compression, for example, the compressed data refers to data after the quantization compression processing. For example, 100M of data is compressed based on a 8bit quantization technique to obtain 25M of data, where 25M of data may be 2N pieces of compressed data, and each piece of compressed data has a size of 8bit. The bit width of the compressed data may be a predetermined bit width. For example, the electronic device obtains 5 pieces of compressed data after data compression, and each piece of compressed data may be 8bit of data. For example, the compressed data may be a 64-dimensional vector, and each component is represented by 8bit. It should be noted that the bit width of the compressed data may also be other bit widths (for example, the compressed data may also be data of 4bit), which is not limited in the embodiments of the present disclosure.

The compression weight is a weight corresponding to the compressed data. For example, when the compressed data is decompressed, the compressed data is multiplied by the compression weight to acquire the decompressed data corresponding to the compressed data. Optionally, a bit width of the compressed data is 2 times a bit width of the compression weight, and N is a positive integer. For example, if the bit width of the compressed data is 4bit, the bit width of the compression weight may be 2bit; if the bit width of the compressed data is 8bit, the bit width of the compression weight is 4bit. For example, the compression weight may be a 64-dimensional vector, and each component is represented by 4bit.

Optionally, the bit width of the compressed data may be the same as a minimum computation bit width of a CPU of the electronic device. For example, if the CPU of the electronic device may process the data of 8bit each time, the minimum computation bit width of the CPU of the electronic device is 8bit, and the bit width of each piece of compressed data may also be 8bit. It should be noted that the bit width of the compressed data may also be any bit width, which is not limited in the embodiments of the present disclosure.

It should be noted that, when compressing the data, since the bit width of the compression weight is smaller than the bit width of the compressed data, the occupied memory after data compression is smaller, thereby saving the storage space of the electronic device. For example, in an actual application process, when the speech recognition model is set in the terminal device (for example, a mobile phone), since the storage space of the terminal device is small, the memory occupied by the compressed data of the speech recognition model is small, the electronic device may compress the data of the speech recognition model based on the 8bit quantization technique, and compress the weight corresponding to the compressed data based on the quantization technique of 4bit, so that the memory occupied after data compression can be effectively reduced, thereby saving the memory of the electronic device.

Optionally, the electronic device may obtain the 2N pieces of compressed data and the compression weight associated with each compressed data in the database. For example, after the electronic device compresses the speech recognition model (or may be a server compresses the speech recognition model) to obtain the compressed data and the compression weight corresponding to the speech recognition model. The compressed data and the compression weight may be stored in a database, and when the electronic device needs to decompress the speech recognition model, the electronic device may obtain the above compressed data and the compression weight in the database.

S202: store, in an interleaved manner, the 2N compression weights to a first register, store the first N pieces of compressed data in the 2N pieces of compressed data to a second register, and store the last N pieces of compressed data in the 2N pieces of compressed data to a third register.

Optionally, the register is configured to register data. For example, the register may include a plurality of storage units (e.g., flip-flops), and a plurality of binary codes may be registered in the register. Optionally, the first register is configured to store 2N compression weights. For example, 2N compression weights may be stored, in an interleaved manner, to the first register.

Optionally, the first register may include N storage units, and the storage unit is configured to store data. For example, the first register may include 4 storage units, and 8bit of data may be stored in each storage unit.

The storage structure of the first register is described below with reference to FIG. 3.

FIG. 3 is a schematic diagram of a storage structure of a first register according to an embodiment of the present disclosure. Referring to FIG. 3, a first register is included. The first register may include a storage unit 1, a storage unit 2, a storage unit 3, and a storage unit 4. Each storage unit may include high bits and low bits. When the first register is operating, the low bits are first operated, and then the high bits are operated.

Optionally, the electronic device may store, in an interleaved manner, the 2N compression weights to the first register based on the following feasible implementation manner: store the first N compression weights in the high bits in the N storage units, and store the last N compression weights in the low bits in the N storage units, respectively. For example, each storage unit in the first register may store 8bit of data, and since the bit width of the compression weight is 4bit, 2 compression weights may be stored in each storage unit. For example, the compression weight after the original data compression includes W1, W2, W3, W4, W5, W6, W7, and W8 (eight compression weights arranged in sequence), where W1 and W5 may be registered in the first storage unit in the first register, W2 and W6 may be registered in the second storage unit in the first register, W3 and W7 may be registered in the third storage unit in the first register, and W4 and W8 may be registered in the fourth storage unit in the first register.

It should be noted that, when W1 and W2 are registered in the first storage unit in the first register, the W1 may register at a high bits in the first storage unit, and W2 may be registered in low bits in the first storage unit, and in an actual application process, 2N compression weights may be pre-arranged in a interleaved manner (for example, the first compression weight and the Nth compression weight are arranged together, the second compression weight and the (N+1)th compression weight are arranged together, etc.), and are stored in a database, and after the electronic device obtains the 2N compression weights in the database, the 2N compression weights may be directly stored in the first register in sequence, so that the 2N pieces of compressed data may be directly stored, in an interleaved manner, in the first register, thereby improving data processing efficiency.

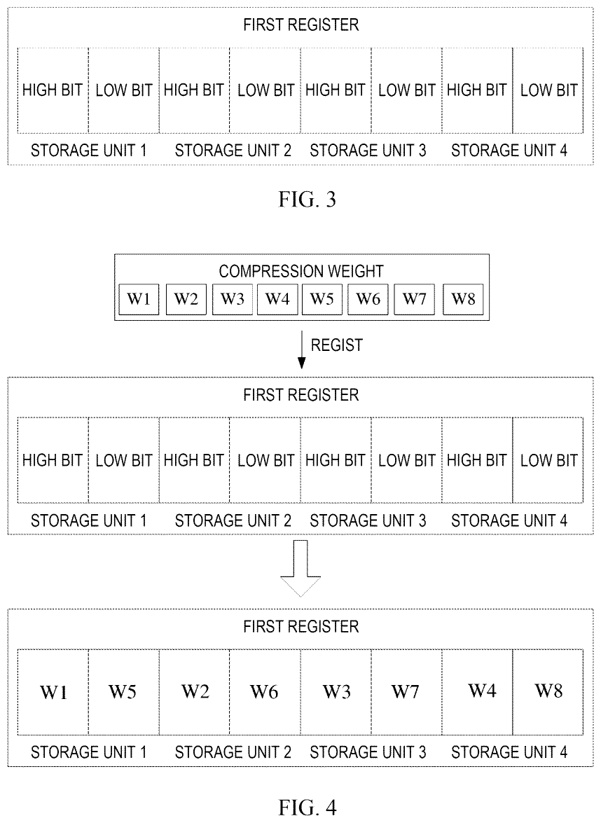

The process of storing, in an interleaved manner, the compression weight to the first register is described below with reference to FIG. 4, taking the compression weight of 8 4bit as an example.

FIG. 4 is a schematic diagram of storing, in an interleaved manner, compression weights according to an embodiment of the present disclosure. Referring to FIG. 4, a first register and a compression weight W1, W2, . . . , W8 are included. The first register may include a storage unit 1, a storage unit 2, a storage unit 3, and a storage unit 4. Each storage unit may include high bits and low bits.

Referring to FIG. 4, W1 is registered at high bits of the storage unit 1, W5 is registered at low bits of the storage unit 1, W2 is registered at high bits of the storage unit 2, W6 is registered at low bits of the storage unit 2, W3 is registered at high bits of the storage unit 3, W7 is registered at low bits of the storage unit 3, the W4 is registered at high bits of the storage unit 4, and the W8 is registered at low bits of the storage unit 4. As such, 8 compression weights may be stored in the first register in an interleaved manner.

Optionally, the second register includes N storage units, and the electronic device may store the first N pieces of compressed data in the 2N pieces of compressed data into the second register. For example, the electronic device may store the first N pieces of compressed data in the N storage units of the second register, respectively.

Optionally, the third register includes N storage units, and the electronic device may store the last N pieces of compressed data in the 2N pieces of compressed data into the third register. For example, the electronic device may respectively store the last N pieces of compressed data in the N storage units of the third register.

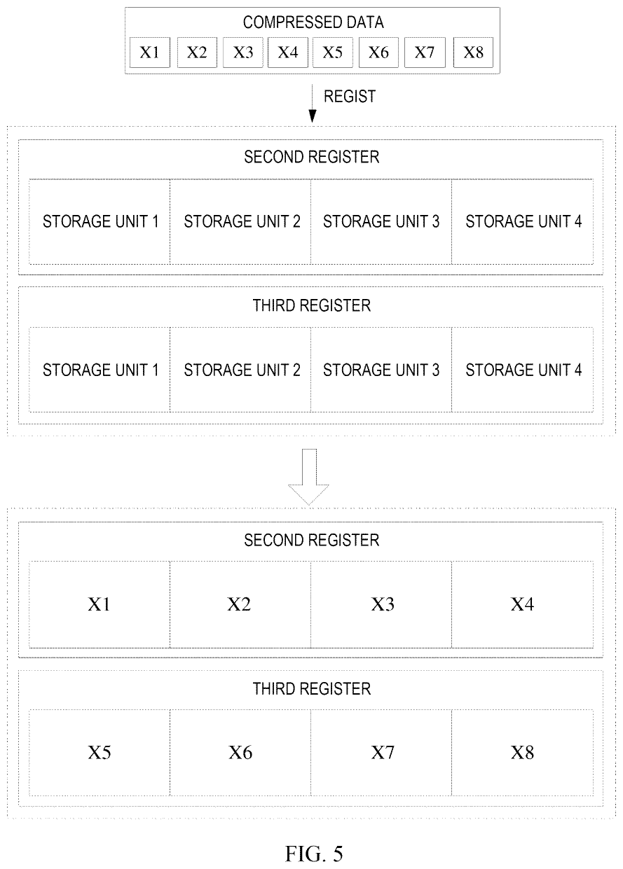

The process of storing the compressed data is described below with reference to FIG. 5 by taking 8 8bit compressed data as an example.

FIG. 5 is a schematic diagram of a storage process of compressed data according to an embodiment of the present disclosure. Referring to FIG. 5, a second register, a third register, and compressed data X1, X2, . . . , X8 are included. The second register may include a storage unit 1, a storage unit 2, a storage unit 3, and a storage unit 4. The third register may include a storage unit 1, a storage unit 2, a storage unit 3, and a storage unit 4, each compressed data is 8bit and each storage unit may register 8bit of data.

Referring to FIG. 5, X1 is registered in the storage unit 1 of the second register, X2 is registered in the storage unit 2 of the second register, X3 is registered in the storage unit 3 of the second register, X4 is registered in the storage unit 4 of the second register, X5 is registered in the storage unit 1 of the third register, X6 is registered in the storage unit 2 of the third register, X7 is registered in the storage unit 3 of the third register, and X8 is registered in the storage unit 4 of the third register. In this way, the electronic device may register 8 pieces of compressed data in the storage units of the second register and the third register, respectively.

S203: decompress data in the first register, the second register, and the third register to acquire decompressed data corresponding to the 2N pieces of compressed data.

Optionally, the decompressed data may be the original data before compressing the 2N compressed data, and the electronic device may obtain the decompressed data corresponding to the 2N pieces of compressed data based on the following feasible implementation: write 0 in the high bits of each storage unit and write 1 at low bits of each of the N storage units included in the fourth register. The fourth register includes N storage units, high bits of each storage unit is 0, and low bits of each storage unit is 1. For example, the fourth register may include 4 storage units, and 8bit of data may be registered in each storage unit, high bits of each storage unit may be 0000, and low bits of each storage unit may be 1111. Optionally, the electronic device may store 0000 at the high bits in the storage unit of the register, and store 1111 at the low bits to obtain the fourth register.

It should be noted that, in an actual application process, 4 registers (the first register, the second register, the third register, and the fourth register) may be set in the electronic device, and the electronic device may alternatively replace the data in the same register to obtain another register, for example, replace the first N pieces of compressed data in the second register with the last N pieces of compressed data, and the register is the third register, which is not limited in the embodiment of the present disclosure.

Optionally, the decompressed data is acquired based on the data in the first register, the second register, the third register, and the fourth register. For example, the data in the first register, the second register, and the third register are processed through the data in the fourth register, so that the first N compression weights in the first register are respectively multiplied by the first N pieces of compressed data in the second register, such that the last N compression weights in the first register are respectively multiplied by the last N pieces of compressed data in the third register, and then the compressed data in the second register and the compressed data in the third register are decompressed to acquire the decompressed data.

The embodiment of the disclosure provides a method for data processing, comprising: obtaining 2N pieces of compressed data and 2N compression weights associated with the 2N pieces of the compressed data, wherein the bit width of the compressed data is 2 times the bit width of the compression weight; respectively storing the first N compression weights in the high bits in the N storage units of the first register, respectively storing the last N compression weights in the low bits in the N storage unit; storing the first N pieces of compressed data in the 2N pieces of compressed data into a second register, storing the last N pieces of compressed data in the 2N pieces of compressed data into a third register, and writing 0 at high bits of each storage unit and write 1 at low bits of each storage unit in the N storage units comprised in the fourth register; and acquiring decompressed data based on the data in the first register, second register, third register and fourth register. In this way, since the 2N compression weights are stored in the first register in an interleaved manner, therefore, based on the data in the first register and fourth register, the first N compression weights may be respectively multiplied by the first N pieces of compressed data in the second register, and the last N compression weights may be respectively multiplied by the last N pieces of compressed data in the third register, thereby decompressing the 2N pieces of compressed data, and improving the accuracy of data decompression.

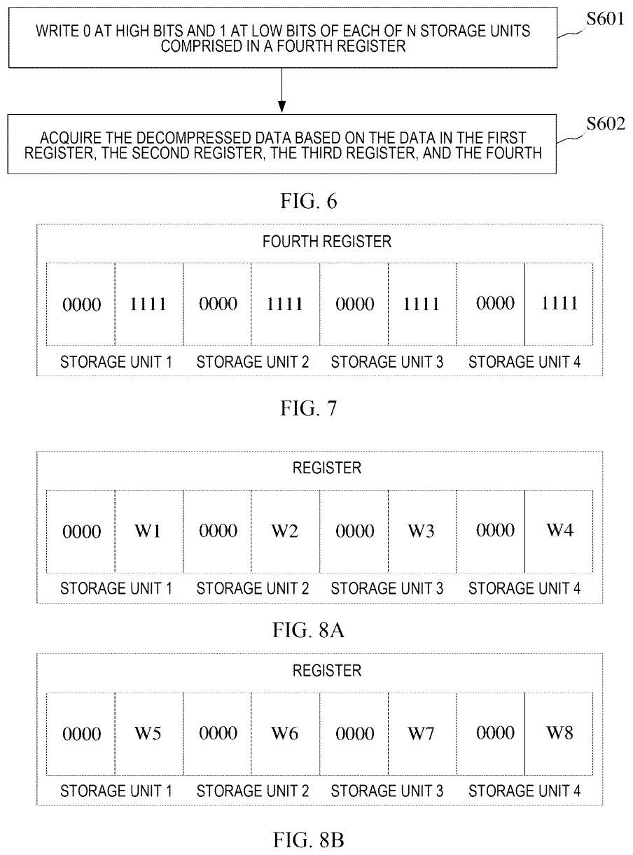

Based on the embodiment shown in FIG. 2, in conjunction with FIG. 6, the data in the first register, the second register, and the third register in the foregoing data processing method are processed to obtain the decompressed data corresponding to the 2N compressed data.

FIG. 6 is a schematic diagram of a method for obtaining decompressed data according to an embodiment of the present disclosure. Referring to FIG. 6, the process of the method comprises:
S601: write 0 at high bits and 1 at low bits of each of N storage units comprised in a fourth register.

Optionally, the fourth register includes N storage units, high bits of each storage unit is 0, and low bits of each storage unit is 1.

The fourth register is described below with reference to FIG. 7.

FIG. 7 is a schematic diagram of a fourth register according to an embodiment of the present disclosure. Referring to FIG. 7, a fourth register is included. The fourth register may include a storage unit 1, a storage unit 2, a storage unit 3, and a storage unit 4. The high bits of the storage unit 1 are 0000, the low bits of the storage unit 1 are 1111, the high bits of the storage unit 2 are 0000, the low bits of the storage unit 2 are 1111, the high bits of the storage unit 3 are 0000, the low bits of the storage unit 3 are 1111, the high bits of the storage unit 4 are 0000, and the low bits of the storage unit 4 are 1111.

S602: acquire the decompressed data based on the data in the first register, the second register, the third register, and the fourth register.

Optionally, the electronic device may acquire the decompressed data based on the following feasible implementation manners: determining the first to-be-processed data based on the data in the first register and the data in the fourth register, determining the second to-be-processed data based on the data in the first register and the data in the fourth register, and acquiring the decompressed data based on the first to-be-processed data, the second to-be-processed data, and the data in the second register and the third register.

Optionally, when the first to-be-processed data is written into the N storage units included in the register, the high bits of the N storage units are 0 and the low bits are the first N compression weights respectively, and when the second to-be-processed data is written into the N storage units included in the register, the high bits of the N storage units are 0, and the low bits are respectively the last N compression weights. In this way, the high bits of the first to-be-processed data and the second to-be-processed data in the register are both 0, so the compression weights in the first to-be-processed data and the second to-be-processed data may be multiplied by the corresponding compressed data, to acquire the decompressed data, thereby improving the accuracy of decompression.

The first to-be-processed data and the second to-be-processed data are described below with reference to FIGS. 8A-8B.

FIG. 8A is a schematic diagram of first to-be-processed data according to an embodiment of the present disclosure. Referring to FIG. 8A, a register is included. The register may include a storage unit 1, a storage unit 2, a storage unit 3, and a storage unit 4. The data in the register is the first to-be-processed data, the high bits of the storage unit 1 are 0000, the low bits of the storage unit 1 are the compression weight W1, the high bit of the storage unit 2 are 0000, the low bits of the storage unit 2 are the compression weight W2, the high bits of the storage unit 3 are 0000, the low bits of the storage unit 3 are the compression weight W3, the high bits of the storage unit 4 are 0000, and the low bits of the storage unit 4 are the compression weight W4.

FIG. 8B is a schematic diagram of second to-be-processed data according to an embodiment of the present disclosure. Referring to FIG. 8B, a register is included. The register may include a storage unit 1, a storage unit 2, a storage unit 3, and a storage unit 4. The data in the register is the second to-be-processed data, the high bits of the storage unit 1 are 0000, the low bits of the storage unit 1 are the compression weight W5, the high bits of the storage unit 2 are 0000, the low bits of the storage unit 2 are the compression weight W6, the high bits of the storage unit 3 are 0000, the low bits of the storage unit 3 are the compression weight W7, the high bits of the storage unit 4 are 0000, and the low bits of the storage unit 4 are the compression weight W8.

Optionally, determining the first to-be-processed data based on the data in the first register and the data in the fourth register includes: shifting the 2N compression weights in the first register to the right to acquire a shifted first register, and multiplying data in the shifted first register and the data in the fourth register to acquire the first to-be-processed data. Optionally, the first N compression weights in the shifted first register being located at low bits in the N storage units.

It should be noted that, in the actual application process, since the first compression weight in the first register shifts to the right by one bit, thus the high bits in the first storage unit of the first register may be filled by 0000.

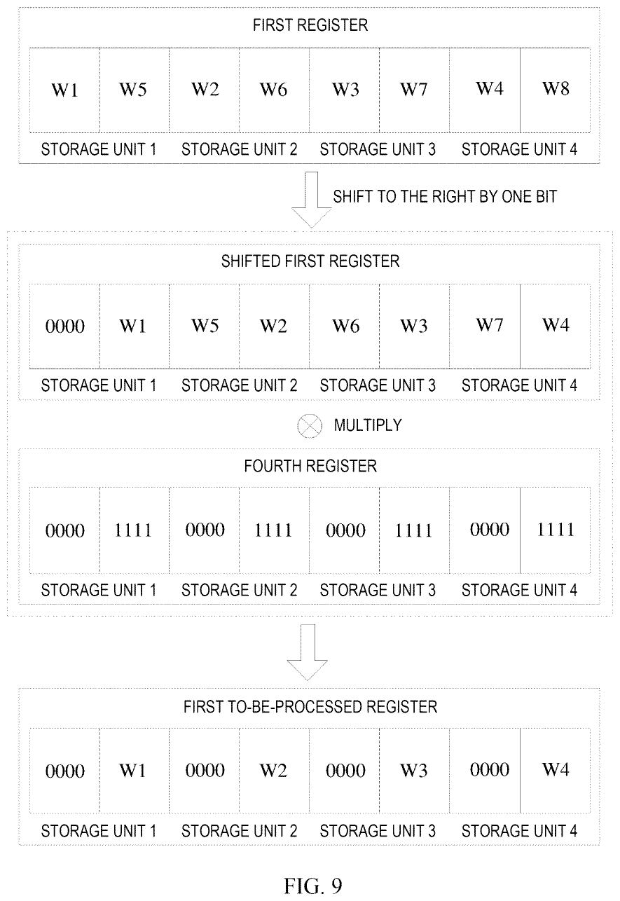

The process of obtaining the first to-be-processed data is described below with reference to FIG. 9.

FIG. 9 is a schematic diagram of a process of obtaining first to-be-processed data according to an embodiment of the present disclosure. Referring to FIG. 9, a first register and a fourth register are included. The first register and the fourth register each include 4 storage units, the high bits of the storage units of the first register are respectively the compression weight W1, the compression weight W2, the compression weight W3, and the compression weight W4, the low bits of the storage units of the first register are respectively the compression weight W5, the compression weight W6, the compression weight W7, and the compression weight W8, the high bits of each storage unit of the fourth register are 0000, and the low bits of each storage unit of the fourth register are all 1111.

Referring to FIG. 9, each pieces of data in the first register is shifted to the right by one bit to acquire a shifted first register, where the high bits of the storage units of the shifted first register are 0000, W5, W6 and W7 respectively, and the low bits of the storage units of the shifted first register are W1, W2, W3 and W4 respectively. Multiplying the shifted first register and the fourth register to acquire a first to-be-processed register. Wherein, the first to-be-processed register includes first to-be-processed data, and high bits of each storage unit of the first to-be-processed register are 0000, and low bits of storage units of the first to-be-processed register are W1, W2, W3, and W4, respectively. In this way, when the first to-be-processed register stores the first to-be-processed data, the high bits in the first to-be-processed register are 0, and the low bits are the first N compression weights, thus the first N compression weights may be separately multiplied by the first N pieces of compressed data to acquire the decompressed data of the first N pieces of compressed data, thereby improving the accuracy of decompression.

Optionally, determining the second to-be-processed data based on the data in the first register and the data in the fourth register includes: multiplying the data in the first register and the data in the fourth register to acquire the second to-be-processed data.

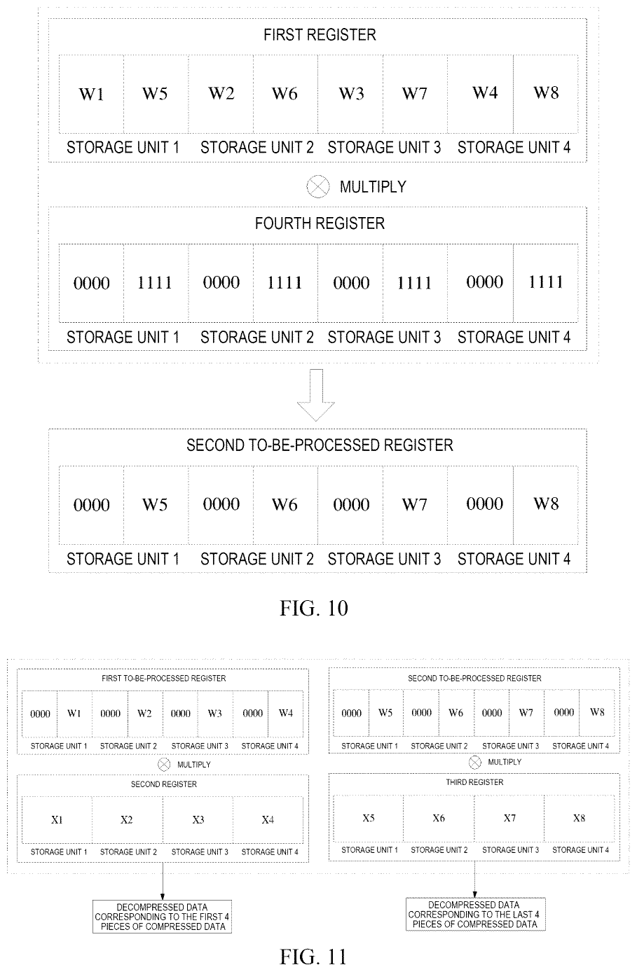

The process of obtaining the second to-be-processed data is described below with reference to FIG. 10.

FIG. 10 is a schematic diagram of obtaining second to-be-processed data according to an embodiment of the present disclosure. Referring to FIG. 10, it includes a first register and a fourth register. The first register and the fourth register each includes 4 storage units, the high bits of the storage units of the first register are W1, W2, W3, and W4 respectively, the low bits of the storage units of the first register are W5, W6, W7, and W8 respectively, the high bits of each storage unit of the fourth register are 0000, and the low bits of each storage unit of the fourth register are all 1111.

Referring to FIG. 10, the data in the first register and the data in the fourth register are directly multiplied to acquire the second to-be-processed register. The second to-be-processed register includes a storage unit 1, a storage unit 2, a storage unit 3, and a storage unit 4. The data in the second to-be-processed register is the second to-be-processed data, the high bits of the storage unit 1 of the second to-be-processed register are 0000, the low bit are W5, the high bits of the storage unit 2 are 0000, the low bits are W6, the high bits of the storage unit 3 are 0000, the low bits are W7, the high bits of the storage unit 4 are 0000, and the low bits are W8. In this way, when the second to-be-processed register stores the second to-be-processed data, the high bits in the second to-be-processed register are 0, and the low bits are the last N compression weights, thus the last N compression weights may be separately multiplied by the last N pieces of compressed data to acquire decompressed data of the last N pieces of compressed data, thereby improving the accuracy of decompression.

Optionally, acquiring the decompressed data based on the first to-be-processed data, the second to-be-processed data, and the data in the second register and the third register comprises: multiplying the first to-be-processed data and the second register to acquire first data; multiplying the second to-be-processed data and the third register to acquire second data; and determining the first data and the second data as the decompressed data. For example, the low bits in the storage units of the first to-be-processed register (the register storing the first to-be-processed data) are the first N compression weights respectively, and the storage units of the second register are the first N pieces of compressed data respectively, so that the first to-be-processed data in the first to-be-processed register is multiplied with the data in the second register, and the first N pieces of compressed data may be decompressed; the low bits in the storage units of the second to-be-processed register (the register storing the second to-be-processed data) are the last N compression weights respectively, and the storage units of the third register are the last N pieces of compressed data respectively, so that the second to-be-processed data in the second to-be-processed register is multiplied with the data in the third register, and the last N pieces of compressed data may be decompressed.

The process of obtaining the decompressed data is described below with reference to FIG. 11.

FIG. 11 is a schematic diagram of a process of obtaining decompressed data according to an embodiment of the present disclosure. Referring to FIG. 11, a first to-be-processed register, a second to-be-processed register, a second register, and a third register are included. Each register includes 4 storage units, the first to-be-processed data is stored in the first to-be-processed register, the second to-be-processed data is stored in the second to-be-processed register, the high bits of the storage units of the first to-be-processed register and the second to-be-processed register are both 0000, the low bits of the storage units of the first to-be-processed register respectively include the compression weights W1, W2, W3, and W4, the low bits of the storage units of the second to-be-processed register respectively include the compression weights W5, W6, W7, and W8, the storage units of the second register include the compressed data X1, X2, X3, and X4, respectively, and the storage units of the third register include the compressed data X5, X6, X7, and X8, respectively.

Referring to FIG. 11, the first to-be-processed data in the first to-be-processed register is multiplied by the data in the second register, the compression weight W1 is multiplied by the compressed data X1, the compression weight W2 is multiplied by the compressed data X2, the compression weight W3 is multiplied by the compressed data X3, and the compression weight W4 is multiplied by the compressed data X4 to acquire the decompressed data corresponding to the first 4 pieces of compressed data.

Referring to FIG. 11, the second to-be-processed data in the second to-be-processed register is multiplied by the data in the third register, the compression weight W5 is multiplied by the compressed data X5, the compression weight W6 is multiplied by the compressed data X6, the compression weight W7 is multiplied by the compressed data X7, the compression weight W8 is multiplied by the compressed data X8, and then the decompressed data corresponding to the last 4 pieces of compressed data is obtained. In this way, although the minimum computation bit width of the electronic device is 8bit and the compression weight is 4bit quantization compression, and the electronic device may decompress the compressed data based on the compression weight to improve the accuracy of the decompressed data.

The embodiment of the present disclosure provides a method for obtaining decompressed data, which comprises the following steps of: writing 0 at high bits and writing 1 at low bits of each storage unit in N storage units comprised in a fourth register; acquiring first to-be-processed data and second to-be-processed data based on the first register and the fourth register; and acquiring decompressed data based on the first to-be-processed data, the second to-be-processed data, and the data in the second register and the third register. In this way, if the minimum computation bit width of the electronic device is 8bit, the compression weight is compressed by using the quantization technique of 4bit, so that the memory of the electronic device can be effectively saved, and by the above method, the electronic device can also calculate the compression weight of 4bit, thereby decompressing the compressed data, avoiding the problem of inaccurate decompressed data caused by force decompression, and improving the accuracy of the decompressed data.

Based on any one of the foregoing embodiments, a process of the foregoing method for data processing is described below with reference to FIG. 12.

FIG. 12 is a schematic flowchart of a method for data processing according to an embodiment of the present disclosure. Referring to FIG. 12, a first register, a second register, a third register and a fourth register are included. Each register includes 4 storage units. The high bits of the storage units of the first register include the compression weights W1, W2, W3, and W4, respectively, the low bits of the storage units of the first register include the compression weights W5, W6, W7, and W8, respectively, the storage units of the second register include the compressed data X1, X2, X3, and X4, respectively, the storage units of the third register respectively include X5, X6, X7, and X8, the high bits of the storage units of the fourth register are both 0000 and the low bit are all 1111.

Referring to FIG. 12, the first register and the fourth register are multiplied to acquire a second to-be-processed register, where the second to-be-processed register stores the second to-be-processed data, the high bits of the storage units of the second to-be-processed register are 0000, and the low bits include the compression weights W5, W6, W7, and W8, respectively. The second to-be-processed register is multiplied by the third register, the compression weight W5 is multiplied by the compressed data X5, the compression weight W6 is multiplied by the compressed data X6, the compression weight W7 is multiplied by the compressed data X7, the compression weight W8 is multiplied by the compressed data W8, and then the decompressed data corresponding to the last 4 pieces of compressed data is acquired.

Referring to FIG. 12, each piece of data in the first register is shifted to the right by one bit to obtain a shifted first register, where the high bits of the storage units of the shifted first register are 0000, W5, W6 and W7 respectively, and the low bits of the storage units of the shifted first register are W1, W2, W3 and W4 respectively. Multiplying the shifted first register and the fourth register to acquire a first to-be-processed register. Data stored in the first to-be-processed register is first to-be-processed data, high bits of each storage unit in the first to-be-processed register are 0000, and low bits of storage units in the first to-be-processed register are W1, W2, W3, and W4, respectively.

Referring to FIG. 12, the first to-be-processed data in the first to-be-processed register is multiplied by the data in the second register, the compression weight W1 is multiplied by the compressed data X1, the compression weight W2 is multiplied by the compressed data X2, the compression weight W3 is multiplied by the compressed data X3, and the compression weight W4 is multiplied by the compressed data X4 to acquire the decompressed data corresponding to the first 4 pieces of compressed data. In this way, since the bit width of the compression weight is ½ of the bit width of the compressed data, the memory of the electronic device can be effectively saved, and by the above method, even if the minimum computation bit width of the electronic device is 8bit, the electronic device can calculate the compression weight of 4bit, thereby decompressing the compressed data, avoiding the problem of inaccurate decompressed data caused by force decompression, and improving the accuracy of the decompressed data.

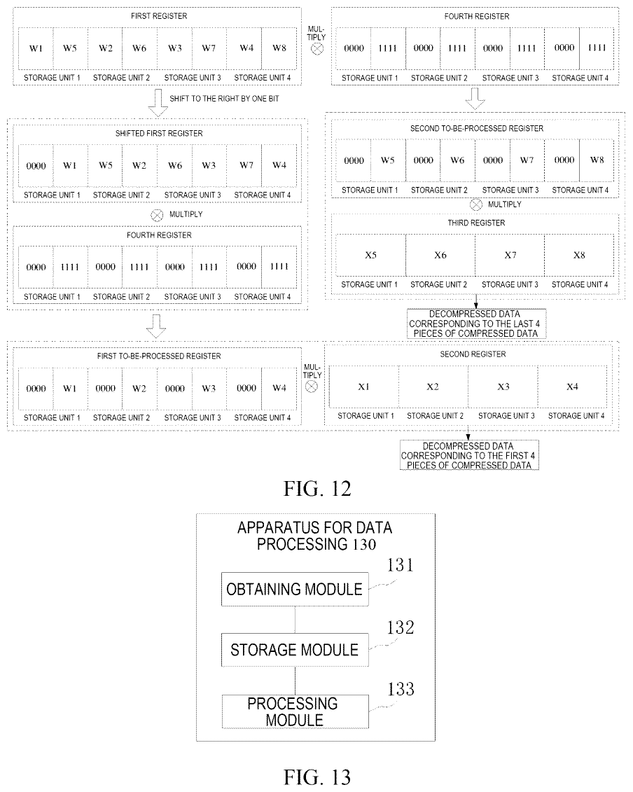

FIG. 13 is a schematic structural diagram of an apparatus for data processing according to an embodiment of the present disclosure. Referring to FIG. 13, the apparatus for data processing 130 includes an obtaining module 131, a storage module 132, and a processing module 133, wherein:
the obtaining module 131 is configured to obtain 2N pieces of compressed data and 2N compression weights associated with the 2N pieces of compressed data, a bit width of the compressed data is 2 times a bit width of the compression weight, and N is a positive integer;
the storage module 132 is configured to store, in an interleaved manner, the 2N compression weights to a first register, store the first N pieces of compressed data in the 2N pieces of compressed data to a second register, and store the last N pieces of compressed data in the 2N pieces of compressed data to a third register;
the processing module 133 is configured to decompress data in the first register, the second register, and the third register to acquire decompressed data corresponding to the 2N pieces of compressed data.

According to one or more embodiments of the present disclosure, the storage module 132 is specifically configured to:
store the first N compression weights in high bits of the N storage units, respectively;
store the last N compression weights in low bits of the N storage units, respectively.

According to one or more embodiments of the present disclosure, the processing module 133 is specifically configured to:
write 0 at high bits and 1 at low bits of each of N storage units comprised in a fourth register;
acquire the decompressed data based on the data in the first register, the second register, the third register, and the fourth register.

According to one or more embodiments of the present disclosure, the processing module 133 is specifically configured to:
determine first to-be-processed data based on the data in the first register and the data in the fourth register, wherein when the first to-be-processed data is written into N storage units comprised in a register, the high bits of the N storage units are 0, and the low bits are respectively the first N compression weights;
determine second to-be-processed data based on the data in the first register and the data in the fourth register, wherein when the second to-be-processed data is written into N storage units comprised in a register, the high bits of the N storage units are 0, and the low bits are respectively the last N compression weights;
acquire the decompressed data based on the first to-be-processed data, the second to-be-processed data, and the data in the second register and the third register.

According to one or more embodiments of the present disclosure, the processing module 133 is specifically configured to:
shift the 2N compression weights in the first register to the right to acquire a shifted first register, the first N compression weights in the shifted first register being located at low bits in the N storage units;
multiply data in the shifted first register and the data in the fourth register to acquire the first to-be-processed data.

According to one or more embodiments of the present disclosure, the processing module 133 is specifically configured to:
multiply the data in the first register and the data in the fourth register to acquire the second to-be-processed data.

According to one or more embodiments of the present disclosure, the processing module 133 is specifically configured to:
Multiply the first to-be-processed data and the data in the second register to acquire first data;
multiply the second to-be-processed data and the data in the third register to acquire second data; and
determine the first data and the second data as the decompressed data.

The apparatus for data processing provided in the embodiments of the present disclosure may be configured to perform the technical solutions in the foregoing method embodiments, and implementation principles and technical effects thereof are similar, and details are not described herein again in this embodiment.

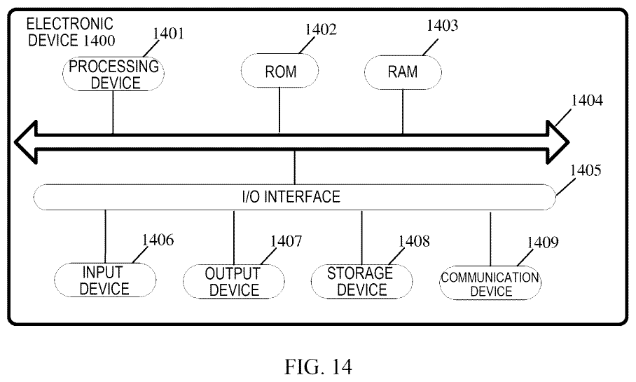

FIG. 14 is a schematic structural diagram of an electronic device according to an embodiment of the present disclosure. FIG. 14 is a schematic structural diagram of an electronic device 1400 suitable for implementing embodiments of the present disclosure, and the electronic device 1400 may be a terminal device or a server. The terminal device may include, but is not limited to, a mobile terminal such as a mobile phone, a notebook computer, a digital broadcast receiver, a personal digital assistant (PDA), a tablet computer (PAD), a portable multimedia player (PMP), an in-vehicle terminal (for example, an in-vehicle navigation terminal), and a fixed terminal such as a digital TV, a desktop computer, or the like. The electronic device shown in FIG. 14 is merely an example, and should not impose any limitation on the functions and scope of use of the embodiments of the present disclosure.

As shown in FIG. 14, the electronic device 1400 may include a processing device (for example, a central processing unit, a graphics processor, etc.) 1401, which may perform various appropriate actions and processing according to a program stored in a read only memory (ROM) 1402 or a program loaded into a random access memory (RAM) 1403 from a storage device 1408. In the RAM 1403, various programs and data required by the operation of the electronic device 1400 are also stored. The processing device 1401, the ROM 1402, and the RAM 1403 are connected to each other through a bus 1404. Input/output (I/O) interface 1405 is also connected to bus 1404.

Generally, the following devices may be connected to the I/O interface 1405: an input device 1406 including, for example, a touch screen, a touch pad, a keyboard, a mouse, a camera, a microphone, an accelerometer, a gyroscope, etc.; an output device 1407 including, for example, a liquid crystal display (LCD), a speaker, a vibrator, etc.; a storage device 1408 including, for example, a magnetic tape, a hard disk, etc.; and a communication device 1409. The communication device 1409 may allow the electronic device 1400 to communicate wirelessly or wired with other devices to exchange data. While FIG. 14 shows an electronic device 1400 having various devices, it should be understood that it is not required to implement or have all illustrated devices. More or fewer devices may alternatively be implemented or provided.

In particular, according to an embodiment of the present disclosure, the process described above with reference to the flowchart may be implemented as a computer software program. For example, embodiments of the present disclosure include a computer program product comprising a computer program embodied on a computer readable medium, the computer program comprising program code for performing the method shown in the flowchart. In such embodiments, the computer program may be downloaded and installed from the network through the communication device 1409, or installed from the storage device 1408, or from the ROM 1402. When the computer program is executed by the processing device 1401, the foregoing functions defined in the method of the embodiments of the present disclosure are performed.

It should be noted that the computer-readable medium described above may be a computer readable signal medium, a computer readable storage medium, or any combination of the foregoing two. The computer-readable storage medium may be, for example, but not limited to, an electrical, magnetic, optical, electromagnetic, infrared, or semiconductor system, device, or device, or any combination thereof. More specific examples of computer-readable storage media may include, but are not limited to, an electrical connection having one or more wires, a portable computer diskette, a hard disk, a random access memory (RAM), a read-only memory (ROM), an erasable programmable read-only memory (EPROM or Flash memory), an optical fiber, a portable compact disk read-only memory (CD-ROM), an optical storage device, a magnetic storage device, or any suitable combination of the foregoing. In the present disclosure, a computer-readable storage medium may be any tangible medium containing or storing a program that may be used by or in connection with an instruction execution system, apparatus, or device. In the present disclosure, a computer readable signal medium may include a data signal propagated in baseband or as part of a carrier, where the computer readable program code is carried. Such propagated data signals may take a variety of forms including, but not limited to, electromagnetic signals, optical signals, or any suitable combination of the foregoing. The computer readable signal medium may also be any computer readable medium other than a computer readable storage medium that may send, propagate, or transmit a program for use by or in connection with an instruction execution system, apparatus, or device. The program code embodied on the computer-readable medium may be transmitted with any suitable medium, including, but not limited to: wires, optical cables, RF (radio frequency), and the like, or any suitable combination of the foregoing.

The computer-readable medium described above may be included in the electronic device; or may be separately present without being assembled into the electronic device.

The computer-readable medium carries one or more programs, and when the one or more programs are executed by the electronic device, the electronic device is enabled to perform the method shown in the foregoing embodiments.

Computer program code for performing the operations of the present disclosure may be written in one or more programming languages, including object oriented programming languages, such as Java, Smalltalk, C++, and conventional procedural programming languages, such as the “C” language or similar programming languages. The program code may execute entirely on a user computer, partially on a user computer, as a stand-alone software package, partially on a user computer, partially on a remote computer, or entirely on a remote computer or server. In the case of a remote computer, the remote computer may be connected to the user computer through any kind of network, including a local area network (LAN) or a wide area network (WAN), or may be connected to an external computer (for example, using an Internet service provider for Internet connection).

The flowcharts and block diagrams in the figures illustrate architecture, functionality, and operation of possible implementations of systems, methods, and computer program products according to various embodiments of the present disclosure. In this regard, each block in the flowchart or block diagram may represent a module, program segment, or portion of code that includes one or more executable instructions for implementing the specified logical function. It should also be noted that in some alternative implementations, the functions noted in the blocks may also occur in a different order than that illustrated in the figures. For example, two consecutively represented blocks may actually be performed substantially in parallel, which may sometimes be performed in the reverse order, depending on the functionality involved. It is also noted that each block in the block diagrams and/or flowcharts, as well as combinations of blocks in the block diagrams and/or flowcharts, may be implemented with a dedicated hardware-based system that performs the specified functions or operations, or may be implemented in a combination of dedicated hardware and computer instructions.

The units involved in the embodiments of the present disclosure may be implemented in software, or may be implemented in hardware. For example, the first obtaining unit may be further described as “obtaining at least two units of Internet Protocol addresses”.

The functions described above may be performed, at least in part, by one or more hardware logic components. For example, without limitation, exemplary types of hardware logic components that may be used include: field programmable gate arrays (FPGAs), application specific integrated circuits (ASICs), application specific standard products (ASSPs), system-on-a-chip (SOCs), complex programmable logic devices (CPLDs), and the like.

In the context of the present disclosure, a machine-readable medium may be a tangible medium that may contain or store a program for use by or in connection with an instruction execution system, apparatus, or device. The machine-readable medium may be a machine-readable signal medium or a machine-readable storage medium. The machine-readable medium may include, but is not limited to, electronic, magnetic, optical, electromagnetic, infrared, or semiconductor systems, devices, or devices, or any suitable combination of the foregoing. More specific examples of machine-readable storage media may include electrical connections based on one or more lines, portable computer disks, hard disks, random access memory (RAM), read-only memory (ROM), erasable programmable read-only memory (EPROM or Flash memory), optical fibers, portable compact disc read-only memory (CD-ROM), optical storage devices, magnetic storage devices, or any suitable combination of the foregoing.

It should be noted that the modification of “a” and “a plurality” mentioned in this disclosure is illustrative and not limiting, and those skilled in the art should understand that “one or more” should be understood unless the context clearly indicates otherwise.

The names of messages or information exchanged between multiple devices in embodiments of the present disclosure are for illustrative purposes only and are not intended to limit the scope of such messages or information.

It can be understood that, before the technical solutions disclosed in the embodiments of the present disclosure are used, the types, the usage scope, the usage scenario and the like of personal information related to the present disclosure, should be notified to the user in an appropriate manner according to the relevant laws and regulations and obtain the authorization of the user.

For example, in response to receiving an active request from a user, prompt information is sent to the user to explicitly prompt the user that the requested operation will need to acquire and use the personal information of the user. Therefore, the user can autonomously select whether to provide personal information to software or hardware executing the operation of the technical solution of the present disclosure according to the prompt information.

As an optional but non-limiting implementation, in response to receiving the active request of the user, the manner of sending the prompt information to the user may be, for example, a pop-up window, and the prompt information may be presented in a text manner in the pop-up window. In addition, the pop-up window may further carry a selection control for the user to select “agree” or “not agree” to provide personal information to the electronic device.

It may be understood that the foregoing notification and obtaining a user authorization process is merely illustrative, and does not constitute a limitation on implementations of the present disclosure, and other manners of meeting related laws and regulations may also be applied to implementations of the present disclosure.

It may be understood that the data involved in the technical solution (including but not limited to the data itself, the acquisition or use of the data) should follow the requirements of the corresponding laws and regulations and related regulations. The data may include information, parameters, messages, and the like, such as flow cut indication information.

The above description is merely an illustration of the preferred embodiments of the present disclosure and the principles of the applied technology. It should be understood by those skilled in the art that the disclosure in the present disclosure is not limited to the technical solutions of the specific combination of the above technical features, and should also cover other technical solutions formed by any combination of the above technical features or their equivalent features without departing from the above disclosed concept. For example, the above features are the technical solutions formed by mutually replacing technical features disclosed in the present disclosure (but not limited to).

Further, while operations are depicted in a particular order, this should not be understood to require that these operations be performed in the particular order shown or in sequential order. In certain circumstances, multitasking and parallel processing may be advantageous. Likewise, while several specific implementation details are included in the discussion above, these should not be construed as limiting the scope of the present disclosure. Certain features described in the context of separate embodiments may also be implemented in combination in a single embodiment. Conversely, the various features described in the context of a single embodiment may also be implemented in multiple embodiments either individually or in any suitable sub-combination.

Although the present subject matter has been described in language specific to structural features and/or methodological acts, it is to be understood that the subject matter defined in the appended claims is not necessarily limited to the specific features or acts described above. Rather, the specific features and acts described above are merely exemplary forms of implementing the claims.

1. A method for data processing, comprising:
obtaining 2N pieces of compressed data and 2N compression weights associated with the 2N pieces of compressed data, a bit width of the compressed data being 2 times a bit width of the compression weight, and N being a positive integer;
storing, in an interleaved manner, the 2N compression weights to a first register, storing the first N pieces of compressed data in the 2N pieces of compressed data to a second register, and storing the last N pieces of compressed data in the 2N pieces of compressed data to a third register; and
decompressing data in the first register, the second register, and the third register to acquire decompressed data corresponding to the 2N pieces of compressed data.

2. The method of claim 1, wherein the first register comprises N storage units, and storing the 2N compression weights to the first register in the interleaved manner comprises:
storing the first N compression weights in high bits of the N storage units, respectively; and
storing the last N compression weights in low bits of the N storage units, respectively.

3. The method of claim 1, wherein decompressing the data in the first register, the second register, and the third register to acquire the decompressed data corresponding to the 2N pieces of compressed data comprises:
writing 0 at high bits and 1 at low bits of each of N storage units comprised in a fourth register; and
acquiring the decompressed data based on the data in the first register, the second register, the third register, and the fourth register.

4. The method of claim 3, wherein acquiring the decompressed data based on the data in the first register, the second register, the third register, and the fourth register comprises:
determining first to-be-processed data based on the data in the first register and the data in the fourth register, wherein when the first to-be-processed data is written into N storage units comprised in a register, the high bits of the N storage units are 0, and the low bits are respectively the first N compression weights;
determining second to-be-processed data based on the data in the first register and the data in the fourth register, wherein when the second to-be-processed data is written into N storage units comprised in a register, the high bits of the N storage units are 0, and the low bits are respectively the last N compression weights; and
acquiring the decompressed data based on the first to-be-processed data, the second to-be-processed data, and the data in the second register and the third register.

5. The method of claim 4, wherein determining the first to-be-processed data based on the data in the first register and the data in the fourth register comprises:
shifting the 2N compression weights in the first register to the right to acquire a shifted first register, the first N compression weights in the shifted first register being located at low bits in the N storage units; and
multiplying data in the shifted first register and the data in the fourth register to acquire the first to-be-processed data.

6. The method of claim 4, wherein determining the second to-be-processed data based on the data in the first register and the data in the fourth register comprises:
multiplying the data in the first register and the data in the fourth register to acquire the second to-be-processed data.

7. The method of claim 4, wherein acquiring the decompressed data based on the first to-be-processed data, the second to-be-processed data, and the data in the second register and the third register comprises:
multiplying the first to-be-processed data and the data in the second register to acquire first data;
multiplying the second to-be-processed data and the data in the third register to acquire second data; and
determining the first data and the second data as the decompressed data.

8. (canceled)

9. An electronic device, comprising: a processor and a memory;
the memory storing computer-executable instructions;
the processor executing the computer-executable instructions stored in the memory, such that the processor performs a method for data processing comprising:
obtaining 2N pieces of compressed data and 2N compression weights associated with the 2N pieces of compressed data, a bit width of the compressed data being 2 times a bit width of the compression weight, and N being a positive integer;
storing, in an interleaved manner, the 2N compression weights to a first register, storing the first N pieces of compressed data in the 2N pieces of compressed data to a second register, and storing the last N pieces of compressed data in the 2N pieces of compressed data to a third register; and
decompressing data in the first register, the second register, and the third register to acquire decompressed data corresponding to the 2N pieces of compressed data.

10. (canceled)

11. The electronic device of claim 9, wherein the first register comprises N storage units, and storing the 2N compression weights to the first register in the interleaved manner comprises:
storing the first N compression weights in high bits of the N storage units, respectively; and
storing the last N compression weights in low bits of the N storage units, respectively.

12. The electronic device of claim 9, wherein decompressing the data in the first register, the second register, and the third register to acquire the decompressed data corresponding to the 2N pieces of compressed data comprises:
writing 0 at high bits and 1 at low bits of each of N storage units comprised in a fourth register; and
acquiring the decompressed data based on the data in the first register, the second register, the third register, and the fourth register.

13. The electronic device of claim 12, wherein acquiring the decompressed data based on the data in the first register, the second register, the third register, and the fourth register comprises:
determining first to-be-processed data based on the data in the first register and the data in the fourth register, wherein when the first to-be-processed data is written into N storage units comprised in a register, the high bits of the N storage units are 0, and the low bits are respectively the first N compression weights;
determining second to-be-processed data based on the data in the first register and the data in the fourth register, wherein when the second to-be-processed data is written into N storage units comprised in a register, the high bits of the N storage units are 0, and the low bits are respectively the last N compression weights; and
acquiring the decompressed data based on the first to-be-processed data, the second to-be-processed data, and the data in the second register and the third register.

14. The electronic device of claim 13, wherein determining the first to-be-processed data based on the data in the first register and the data in the fourth register comprises:
shifting the 2N compression weights in the first register to the right to acquire a shifted first register, the first N compression weights in the shifted first register being located at low bits in the N storage units; and
multiplying data in the shifted first register and the data in the fourth register to acquire the first to-be-processed data.

15. The electronic device of claim 13, wherein determining the second to-be-processed data based on the data in the first register and the data in the fourth register comprises:
multiplying the data in the first register and the data in the fourth register to acquire the second to-be-processed data.

16. The electronic device of claim 13, wherein acquiring the decompressed data based on the first to-be-processed data, the second to-be-processed data, and the data in the second register and the third register comprises:
multiplying the first to-be-processed data and the data in the second register to acquire first data;
multiplying the second to-be-processed data and the data in the third register to acquire second data; and
determining the first data and the second data as the decompressed data.

17. A non-transitory computer-readable storage medium, wherein the computer-readable storage medium stores computer-executable instructions, the computer-executable instructions, when executed by a processor, implement a method for data processing comprising:
obtaining 2N pieces of compressed data and 2N compression weights associated with the 2N pieces of compressed data, a bit width of the compressed data being 2 times a bit width of the compression weight, and N being a positive integer;
storing, in an interleaved manner, the 2N compression weights to a first register, storing the first N pieces of compressed data in the 2N pieces of compressed data to a second register, and storing the last N pieces of compressed data in the 2N pieces of compressed data to a third register; and
decompressing data in the first register, the second register, and the third register to acquire decompressed data corresponding to the 2N pieces of compressed data.

18. The non-transitory computer-readable storage medium of claim 17, wherein the first register comprises N storage units, and storing the 2N compression weights to the first register in the interleaved manner comprises:
storing the first N compression weights in high bits of the N storage units, respectively; and
storing the last N compression weights in low bits of the N storage units, respectively.

19. The non-transitory computer-readable storage medium of claim 17, wherein decompressing the data in the first register, the second register, and the third register to acquire the decompressed data corresponding to the 2N pieces of compressed data comprises:
writing 0 at high bits and 1 at low bits of each of N storage units comprised in a fourth register; and
acquiring the decompressed data based on the data in the first register, the second register, the third register, and the fourth register.

20. The non-transitory computer-readable storage medium of claim 19, wherein acquiring the decompressed data based on the data in the first register, the second register, the third register, and the fourth register comprises:
determining first to-be-processed data based on the data in the first register and the data in the fourth register, wherein when the first to-be-processed data is written into N storage units comprised in a register, the high bits of the N storage units are 0, and the low bits are respectively the first N compression weights;
determining second to-be-processed data based on the data in the first register and the data in the fourth register, wherein when the second to-be-processed data is written into N storage units comprised in a register, the high bits of the N storage units are 0, and the low bits are respectively the last N compression weights; and
acquiring the decompressed data based on the first to-be-processed data, the second to-be-processed data, and the data in the second register and the third register.

21. The non-transitory computer-readable storage medium of claim 20, wherein determining the first to-be-processed data based on the data in the first register and the data in the fourth register comprises:
shifting the 2N compression weights in the first register to the right to acquire a shifted first register, the first N compression weights in the shifted first register being located at low bits in the N storage units; and
multiplying data in the shifted first register and the data in the fourth register to acquire the first to-be-processed data.

22. The non-transitory computer-readable storage medium of claim 20, wherein determining the second to-be-processed data based on the data in the first register and the data in the fourth register comprises:
multiplying the data in the first register and the data in the fourth register to acquire the second to-be-processed data.
